(19) United States
(12) Patent Application Publication
(10) Pub. No.: US 2025/0129513 A1
(43) Pub. Date: Apr. 24, 2025

(54) PRODUCTION METHOD FOR NITRIDE CRYSTAL SUBSTRATE AND NITRIDE CRYSTAL SUBSTRATE

(71) Applicant: SUMITOMO CHEMICAL COMPANY, LIMITED, Tokyo (JP)

(72) Inventors: Taichiro KONNO, Hitachi-shi (JP); Masafumi YOKOYAMA, Hitachi-shi (JP); Hajime FUJIKURA, Hitachi-shi (JP)

(73) Assignee: SUMITOMO CHEMICAL COMPANY, LIMITED, Tokyo (JP)

(21) Appl. No.: 18/919,983

(22) Filed: Oct. 18, 2024

(30) Foreign Application Priority Data
Oct. 19, 2023 (JP) 2023-180004

(51) Int. Cl. C30B 25/18; C25F 3/12; C30B 29/40; C30B 33/10; H01L 33/32

(52) U.S. Cl. CPC C30B 25/186; C25F 3/12; C30B 25/183; C30B 29/403; C30B 29/406; C30B 33/10; H10H 20/825

(57) ABSTRACT

To stably obtain a nitride crystal substrate containing AlGaN. A production method for a nitride crystal substrate includes: (a) preparing a base substrate; (b) forming an intermediate layer including n-type group III nitride crystal, above the base substrate; (c) forming a cover layer on the intermediate layer, the cover layer including group III nitride crystal having a carrier concentration lower than a carrier concentration of the intermediate layer; (d) making the intermediate layer porous through dislocations in the cover layer by performing an electrochemical process, while maintaining a surface condition of the cover layer; (e) epitaxially growing a regrowth layer comprising group III nitride crystal, on the cover layer; and (f) peeling off the regrowth layer from the base substrate by using at least a portion of the intermediate layer made porous as a boundary, wherein in (e), crystal represented by a composition formula of AlₓGa₁₋ₓN, where an Al composition ratio x is 0.05 or more and 0.8 or less, is grown as the regrowth layer.

### FIELD AND BACKGROUND OF THE INVENTION

The present disclosure relates to a production method for a nitride crystal substrate and a nitride crystal substrate.

Various production methods for obtaining nitride crystal substrates comprising group III nitride crystal have been disclosed (see, for example, Japanese Patent Laid Open Publication No. 2003-178984, and ECS Journal of Solid State Science and Technology 10 (3), 035001, 2021).

### SUMMARY OF THE INVENTION

The present disclosure has an object to stably obtain a nitride crystal substrate containing AlGaN.

According to an aspect of the present disclosure, there is provided a production method for a nitride crystal substrate, comprising:
(a) preparing a base substrate;
(b) forming an intermediate layer including n-type group III nitride crystal, above the base substrate;
(c) forming a cover layer on the intermediate layer, the cover layer including group III nitride crystal having a carrier concentration lower than a carrier concentration of the intermediate layer;
(d) making the intermediate layer porous through dislocations in the cover layer by performing an electrochemical process, while maintaining a surface condition of the cover layer;
(e) epitaxially growing a regrowth layer comprising group III nitride crystal, on the cover layer; and
(f) peeling off the regrowth layer from the base substrate by using at least a portion of the intermediate layer made porous as a boundary, wherein
in (e), crystal represented by a composition formula of AlₓGa₁₋ₓN, where an Al composition ratio x is 0.05 or more and 0.8 or less, is grown as the regrowth layer.

According to another aspect of the present disclosure, there is provided a nitride crystal substrate comprising crystal represented by a composition formula of AlₓGa₁₋ₓN, wherein
an Al composition ratio x of the composition formula is 0.05 or more and 0.8 or less, the nitride crystal substrate satisfies the following formula (1):

$$0.58 \leq a / c \leq 0.66 \qquad ( 1 )$$

where c is a lattice constant in a <0001>-axis direction of the nitride crystal substrate, as determined based on a diffraction angle of a diffraction peak of (0002) of AlGaN by X-ray diffraction measurement, and
a is a lattice constant in a <11-20>-axial direction of the nitride crystal substrate, as determined based on the c and a diffraction angle of a diffraction peak of (10-12) of AlGaN by the X-ray diffraction measurement.

According to the present disclosure, the nitride crystal substrate containing AlGaN can be obtained stably.

### BRIEF DESCRIPTION OF THE DRAWINGS

FIG. 1 is a flowchart showing a production method for a nitride crystal substrate according to one embodiment of the present disclosure.

FIG. 2A is a schematic cross-sectional view showing the production method for a nitride crystal substrate according to the embodiment of the present disclosure.

FIG. 2B is a schematic cross-sectional view showing the production method for a nitride crystal substrate according to the embodiment of the present disclosure.

FIG. 3A is a schematic cross-sectional view showing the production method for a nitride crystal substrate according to the embodiment of the present disclosure.

FIG. 3B is a schematic cross-sectional view showing the production method for a nitride crystal substrate according to the embodiment of the present disclosure.

FIG. 4 is a schematic cross-sectional view showing the production method for a nitride crystal substrate according to the embodiment of the present disclosure.

FIG. 5 is a diagram showing changes in the temperature in a regrowth step according to the embodiment of the present disclosure.

FIG. 6 is a schematic cross-sectional view showing the production method for a nitride crystal substrate according to the embodiment of the present disclosure.

FIG. 7 is a schematic cross-sectional view showing the production method for a nitride crystal substrate according to the embodiment of the present disclosure.

FIG. 8 is a schematic cross-sectional view showing the production method for a nitride crystal substrate according to the embodiment of the present disclosure.

FIG. 9 is a schematic cross-sectional view showing the production method for a nitride crystal substrate according to the embodiment of the present disclosure.

FIG. 10A is a plan view showing a nitride crystal substrate according to one embodiment of the present disclosure.

FIG. 10B is a cross-sectional view showing the nitride crystal substrate according to the embodiment of the present disclosure.

### DETAILED DESCRIPTION

### <Findings Obtained by Inventors>

Light-emitting diodes (LEDs) and laser diodes (LDs) with wavelengths ranging from 365 nm to about 530 nm (green) are achieved by using a substrate comprising gallium nitride (GaN) crystal (hereafter also referred to as a GaN crystal substrate).

On the other hand, for ultraviolet LEDs and ultraviolet LDs with wavelengths shorter than 365 nm, it is necessary to grow a layer comprising aluminum gallium nitride (AlGaN) crystal containing aluminum (Al) (hereinafter referred to as an AlGaN layer). However, in the case of using the GaN crystal substrate described above, it is difficult to achieve a high-quality device due to a lattice mismatch between the AlGaN layer and the GaN crystal substrate. Further, in another case, an AlGaN layer may be grown on an AlN crystal substrate produced by a sublimation method such as that described in ECS Journal of Solid State Science and Technology 10 (3), 035001, 2021. In this case, however, it is also difficult to achieve a high-quality device due to a lattice mismatch between the AlGaN layer and the AlN crystal substrate. For this reason, a high-quality AlGaN crystal substrate needs to be achieved.

Here, a GaN crystal substrate can be obtained, for example, by a void-assisted separation (VAS) method described in Japanese Patent Laid Open Publication No. 2003-178984 described above. The VAS method involves first preparing a template that includes a GaN layer with voids and a mesh-shaped titanium nitride (TiN layer) on a sapphire substrate in this order. Next, a thick GaN main growth layer is grown on the GaN layer and the TiN layer in this state. The GaN main growth layer is then peeled off from the substrate by using the GaN layer with the voids as a boundary. As a result, a GaN crystal substrate can be obtained from the peeled GaN main growth layer.

Alternatively, to obtain a GaN crystal substrate, a GaN main growth layer may be grown on a template where the surface of the GaN layer is covered with a mask that partially has openings.

In any of the above cases, GaN crystal grows in the shape of islands in an initial stage of growth of the GaN main growth layer. Thereafter, as thick GaN crystal is grown, the island-shaped GaN crystals gather to form the GaN main growth layer as a continuous film. In the process of allowing such island-shaped GaN crystals to gather, crystal strain introduced during the growth of the thick GaN crystal is significantly alleviated. As a result, it becomes possible to grow a thick GaN main growth layer without cracks even on a substrate comprising a different type of material.

An aluminum nitride (AlN) crystal substrate can be obtained by the sublimation method, as described in ECS Journal of Solid State Science and Technology 10 (3), 035001, 2021, for example. In this case, an AlN layer is first grown on a substrate comprising a different material, such as a silicon carbide (SiC) substrate, in the initial stage. Next, by using this AlN layer as a seed crystal, the AlN layer is thickened by the sublimation method. An AlN crystal substrate is then obtained by peeling off the substrate comprising the different material from the AlN layer. Once the AlN crystal substrate is obtained, the AlN layer is grown again by the sublimation method with this AlN crystal substrate as the seed crystal, thereby producing an AlN ingot. Thereafter, an AlN crystal substrate is obtained by slicing the AlN ingot.

On the other hand, a method of obtaining an AlGaN crystal substrate becomes more difficult to implement than the method of obtaining a GaN or AlN crystal substrate. First, it is extremely difficult to obtain AlGaN crystal with a desired Al composition by the sublimation method because the vapor pressures of Al and Ga are different from each other. Thus, a practical method involves growing an AlGaN main growth layer on a template, as in the VAS method described above. However, in that case, Al atoms are extremely difficult to move, making it hard to achieve the growth process, including the island-shaped growth, gathering of island-shaped crystals, and planarization of crystal, as in the case of GaN.

In particular, during the three-dimensional growth of island-shaped AlGaN crystal, the movement of Al atoms is reduced as described above, which forms some areas with a high Al composition ratio and other areas with a low Al composition ratio in the plane. Thus, crystal strain tends to occur in the AlGaN main growth layer. As a result, cracks may also occur in the AlGaN main growth layer.

Therefore, to obtain an AlGaN crystal substrate from an AlGaN main growth layer, there is a proposed method that involves first growing a GaN layer thickly to thereby flatten the surface of the GaN layer, followed by the growth of a thick AlGaN main growth layer.

However, even with this method, it is difficult to obtain an AlGaN main growth layer without cracks due to the lattice mismatch between the GaN layer and the AlGaN main growth layer.

Therefore, the inventors have examined the following method as a production method for an AlGaN crystal substrate. First, an intermediate layer and a cover layer, both containing group III nitride crystal, are grown on a base substrate in this order, and an electrochemical process is then performed on this laminated body. Thus, a seed substrate in which the intermediate layer is made porous while maintaining the flatness of the cover layer is fabricated. Next, by using this seed substrate, a regrowth layer comprising AlGaN crystal is grown on the flat cover layer as a continuous film. With such a method, the inventors could solve the above-mentioned problem and succeeded in obtaining an AlGaN crystal substrate without cracks from the regrowth layer.

The present disclosure below is based on the above findings obtained by the inventors.

### Details of Embodiment of Present Disclosure

Next, one embodiment of the present disclosure will be described with reference to the accompanying drawings. The present disclosure is not limited to these examples, but is indicated by the claims and intended to include all changes within the meaning and scope of the claims and equivalents thereof.

### One Embodiment of Present Disclosure

One embodiment of the present disclosure will be described below with reference to the drawings.

### (1) Production Method for Nitride Crystal Substrate

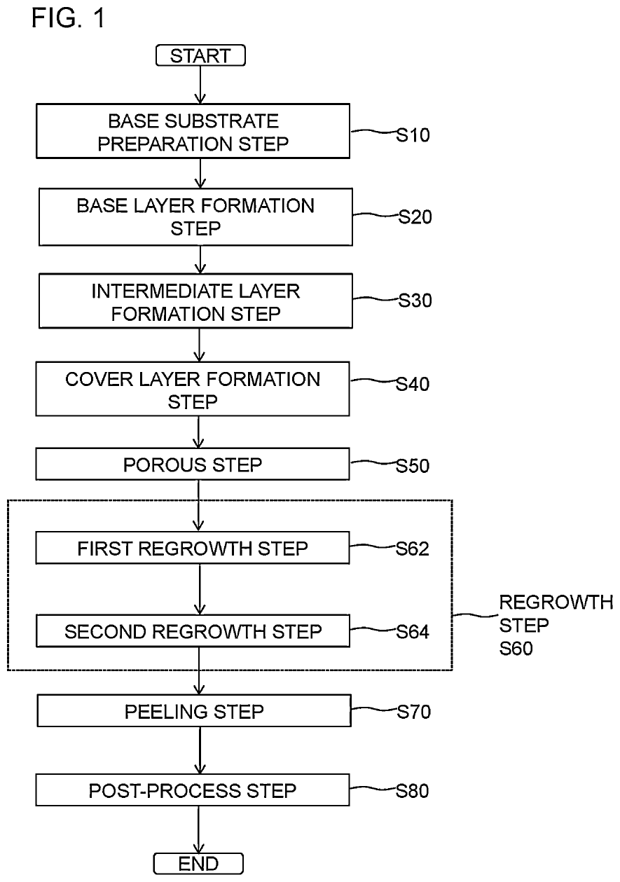

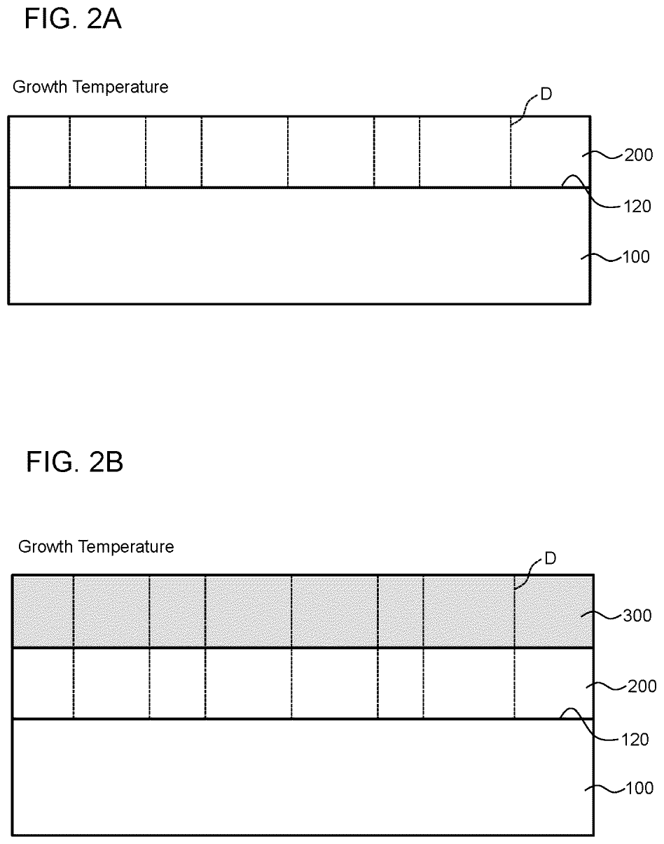

Referring to FIGS. 1 to 9, the production method for a nitride crystal substrate according to the present embodiment is described. In FIGS. 2A to 4 and 6 to 9, hatching of the cross sections except for an intermediate layer 300 is omitted.

In the following, in group III nitride crystal with a wurtzite structure, a <0001>axis (e.g., axis) is referred to as a “c-axis”, and (0001) as a “c-plane”. The (0001) is sometimes referred to as a “+c-plane (group III element polar plane)”, and (000-1) as the “−c-plane (nitrogen (N) polar plane)”. A<1-100>axis is referred to as a “m axis”, and a <11-20>axis as an “a-axis”. The term “carrier concentration” in the present disclosure means a free carrier concentration at room temperature (22° C.).

As shown in FIG. 1, the production method for a nitride crystal substrate according to the present embodiment includes, for example, a base substrate preparation step S10, a base layer formation step S20, an intermediate layer formation step S30, a cover layer formation step S40, a porous step S50, a regrowth step S60, a peeling step S70, and a post-process step S80.

### (S10: Base Substrate Preparation Step)

First, as shown in FIG. 2A, the base substrate 100 is prepared.

In the present embodiment, the base substrate 100 comprising, for example, a material different from group III nitride is prepared. Specifically, the base substrate 100 is, for example, a sapphire substrate, a SiC substrate, a silicon (Si) substrate, or a gallium arsenide (GaAs) substrate. The base substrate 100 may be insulating or conductive. Here, the base substrate 100 is, for example, a sapphire substrate.

The diameter of the base substrate 100 is, for example, 1 inch (25 mm) or more, or may be 2 inches (50 mm) or more, or 4 inches (100 mm) or more. This allows for the growth of a regrowth layer 500 with a large area, described later.

The base substrate 100 has a thickness of, for example, 150 μm or more and 3 mm or less.

The base substrate 100 has a main surface 120, which becomes the growth surface, for example. In a case where the base substrate 100 is a sapphire substrate or SiC substrate, a crystal plane with a low index closest to that of the main surface 120 is, for example, the c-plane (+c-plane). In a case where the base substrate 100 is a Si substrate or GaAs substrate, a crystal plane with the low index closest to that of the main surface 120 is, for example, (001) or (111).

In the present embodiment, the c-plane of the base substrate 100 may be inclined with respect to the main surface 120. That is, the c-axis of the base substrate 100 may be inclined at a predetermined off-angle with respect to the normal of the main surface 120. The off-angle of the base substrate 100 is, for example, 0° or more and 5° or less.

The main surface 120 of the base substrate 100 has an arithmetic mean roughness (Ra) of, for example, less than 0.3 nm.

### (S20: Base Layer Formation Step)

After preparing the base substrate 100, a base layer 200 including group III nitride crystal is formed (the base layer 200 comprising group III nitride crystal is formed) on the base substrate 100, for example, by a vapor phase growth method, as shown in FIG. 2A.

Specifically, an aluminum nitride (AlN) buffer layer is grown by supplying aluminum chloride (AlCl₃) gas and ammonia (NH₃) gas to the base substrate 100 heated to a predetermined growth temperature, for example, using a hydride vapor phase epitaxy (HVPE) method. Next, a gallium nitride (GaN) layer is grown by supplying gallium chloride (GaCl) gas and NH₃ gas to the base substrate 100 heated to the predetermined growth temperature. The growth temperature of each layer is, for example, 900° C. or higher and 1100° C. or lower. In the way above, the AlN buffer layer and the GaN layer are formed as the base layer 200 on the main surface 120 of the base substrate 100 in this order. However, the base layer 200 may not have an AlN buffer layer.

In the present embodiment, the base layer 200 is of, for example, n-type. Specifically, when growing the GaN layer as the base layer 200, dichlorosilane (SiH₂Cl₂) gas is further supplied as an n-type dopant gas to grow a Si-doped GaN layer.

In the present embodiment, a carrier concentration in the GaN layer of the base layer 200 is lower than, for example, a carrier concentration in the intermediate layer 300. In other words, an n-type impurity concentration in the GaN layer of the base layer 200 is lower than, for example, an n-type impurity concentration in the intermediate layer 300. Specifically, the carrier concentration (and n-type impurity concentration) in the base layer 200 is, for example, 2×10¹⁸ cm⁻³ or less, or 1×10¹⁸ cm⁻³ or less. Thus, in the porous step S50 of making the intermediate layer 300 porous by performing the electrochemical process as described later, the base layer 200 can function as an etching stopper located on the lower side of the intermediate layer 300.

The lower limit of the carrier concentration in the GaN layer of the base layer 200 is not limited. However, the carrier concentration in the GaN layer of the base layer 200 may be, for example, 1×10¹⁶ cm⁻³ or more. Thus, since the base layer 200 itself has some conductivity, the etching of the intermediate layer 300 can progress toward a lower portion of the intermediate layer 300 through the electrochemical process during the porous step S50 described later.

The thickness of the base layer 200 is not particularly limited. However, the thickness of the base layer 200 may be, for example, more than 0 nm and 5 μm or less. By setting the thickness of the base layer 200 to 5 μm or less, the total thickness of the laminated layers on the base substrate 100 can be adjusted to, for example, 15 μm or less. This can suppress cracking that would be caused by a difference in linear expansion coefficient between respective layers, including the base substrate 100 and the base layer 200.

In the present embodiment, the crystal plane with the low index closest to the surface of the base layer 200 is the c-plane of the GaN layer. By forming a flat surface of the base layer 200 with this crystal plane in advance, the intermediate layer 300 and a cover layer 400, both having good crystallinity, can be grown on the surface of the base layer 200.

### (S30: Intermediate Layer Formation Step)

After the base layer 200 is formed, the intermediate layer 300 including n-type group III nitride crystal is formed on the base layer 200 located above the base substrate 100, for example, by the vapor phase growth method, as shown in FIG. 2B. (In this step, the intermediate layer 300 comprising group III nitride crystal in a state that does not contain any voids is formed.)

Specifically, a Si-doped GaN layer is grown as the intermediate layer 300 on the base layer 200 using, for example, the HVPE method by supplying GaCl gas, NH₃ gas, and SiH2Cl2 gas as n-type dopant gas to the base substrate 100 heated to the predetermined growth temperature. The intermediate layer 300 is grown with the +c-plane as the growth surface.

In the present embodiment, the carrier concentration in the intermediate layer 300 is higher than, for example, each of the carrier concentrations in the base layer 200 and in the cover layer 400. In other words, the n-type impurity concentration in the intermediate layer 300 is higher than, for example, each of the n-type impurity concentration in the base layer 200 and the n-type impurity concentration in the cover layer 400. Specifically, the carrier concentration (and n-type impurity concentration) in the intermediate layer 300 is, for example, 3×10¹⁸ cm⁻³ or more, or may be 1×10¹⁹ cm⁻³ or more. Thus, in the porous step S50 described later, the intermediate layer 300 can be selectively made porous.

The upper limit of the carrier concentration in the intermediate layer 300 is not limited. However, the carrier concentration in the intermediate layer 300 may be, for example, 1×10²⁰ cm⁻³ or less, or 5×10¹⁹ cm⁻³ or less. This can suppress the degradation of the crystallinity of the intermediate layer 300.

In the present embodiment, the thickness of the intermediate layer 300 is, for example, more than 100 nm, or may be 500 nm or more, or 1 μm or more. This allows large voids to be formed in the intermediate layer 300 in the porous step S50 described later. Thus, in the regrowth step S60 described later, voids 360 in the intermediate layer 300 can be maintained. As a result, in the peeling step S70 described later, the regrowth layer 500 can be easily and stably peeled off from the base substrate 100 by using, as the boundary, at least a portion of the intermediate layer 300 maintained in a porous state.

The upper limit of the thickness of the intermediate layer 300 is not limited. However, the thickness of the intermediate layer 300 may be 10 μm or less. By setting the thickness of the intermediate layer 300 to 10 μm or less, the total thickness of the laminated layers on the base substrate 100 can be adjusted to 15 μm or less, for example. This can suppress cracking that would be caused by a difference in linear expansion coefficient between respective layers, including the base substrate 100 and the intermediate layer 300.

### (S40: Cover Layer Formation Step)

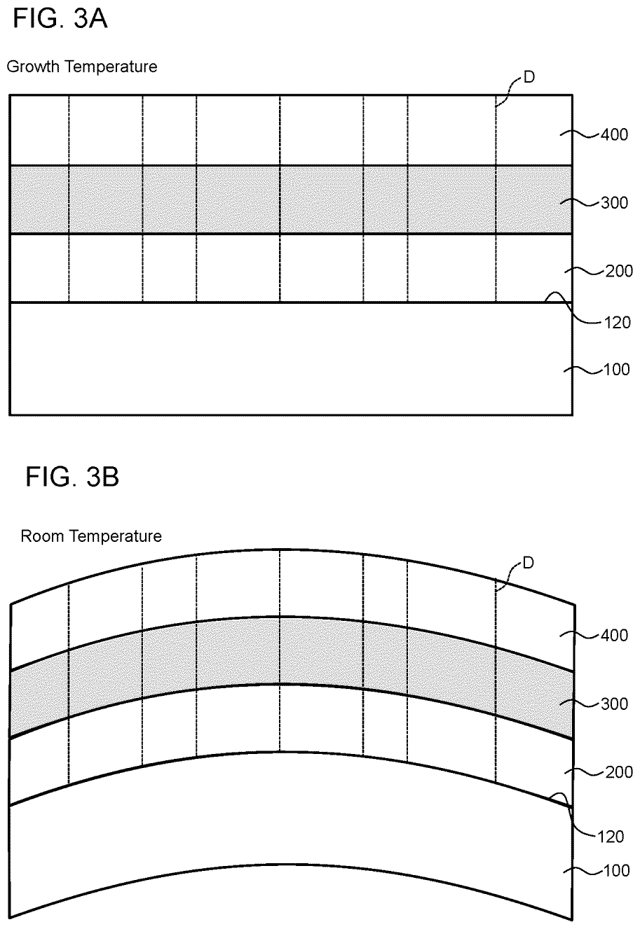

After forming the intermediate layer 300, the cover layer 400 including group III nitride crystal is formed (the cover layer 400 comprising group III nitride crystal is formed) on the intermediate layer 300, for example, by the vapor phase growth method, as shown in FIG. 3A.

In the present embodiment, for example, GaN crystal is grown as the cover layer 400. Thus, the crystal growth of the cover layer 400 can be easily controlled by the vapor phase growth method. As a result, the crystallinity of the cover layer 400 can be stably improved. Furthermore, the carrier concentration of the cover layer 400 can be easily controlled.

Specifically, a Si-doped GaN layer is grown as the cover layer 400 on the intermediate layer 300, for example, by the HVPE method under the same conditions as those in the intermediate layer formation step S30, except that an amount of SiH₂Cl₂ gas supplied as the n-type dopant gas is less than that in the intermediate layer formation step S30. The cover layer 400 is grown with the +c-plane as the growth surface.

In the present embodiment, the carrier concentration in the cover layer 400 is lower than, for example, the carrier concentration in the intermediate layer 300. In other words, the n-type impurity concentration in the cover layer 400 is lower than, for example, the n-type impurity concentration in the intermediate layer 300. Specifically, the carrier concentration (and n-type impurity concentration) in the cover layer 400 is, for example, 1×10¹⁸ cm⁻³ or less. Thus, in the porous step S50 described later, the intermediate layer 300 can be selectively made porous while suppressing etching of the cover layer 400. That is, under a predetermined voltage, the size of the micro voids in the cover layer 400 can be prevented from increasing, whereas the size of the voids 360 in the intermediate layer 300 increases.

The lower limit of the carrier concentration in the cover layer 400 is not limited. However, the carrier concentration in the cover layer 400 may be, for example, 1×10¹⁶ cm⁻³ or more, or 1×10¹⁷ cm⁻³ or more. In this way, since the cover layer 400 itself has conductivity, the intermediate layer 300 can be connected to an anode 842 via the cover layer 400, so that the entire intermediate layer 300 can be equipotential with the anode 842 during the electrochemical process performed in the porous step S50 of making the intermediate layer 300 porous.

Here, in a state where the cover layer formation step S40 is completed, the base layer 200, the intermediate layer 300, and the cover layer 400 have a plurality of dislocations D passing therethrough in the thickness direction, for example. A dislocation density on the surface of the cover layer 400 is, for example, 1×10⁸ cm⁻² or more and 1×10⁹ cm⁻² or less. The dislocations D in the cover layer 400 are used in the porous step S50 below.

In the present embodiment, the thickness of the cover layer 400 is, for example, 10 nm or more and 2 μm or less, or may be 50 nm or more and 1.5 μm or less.

By setting the thickness of the cover layer 400 to 10 nm or more or 50 nm or more, the cover layer 400 can discharge gas generated by outgassing toward the outside of the cover layer 400 through the dislocations D of the cover layer 400 while maintaining the cover layer 400 itself, even when the outgassing of N₂ gas or the like occurs during etching of the intermediate layer 300 in the porous step S50 described later. Thus, the cover layer 400 can be prevented from being peeled off from the intermediate layer 300.

On the other hand, by setting the thickness of the cover layer 400 to 2 μm or less or 1.5 μm or less, the electrolyte is allowed to stably reach the intermediate layer 300 through the dislocations D of the cover layer 400 in the porous step S50 described later. Thus, the voids can be formed stably in the intermediate layer 300.

After growing the cover layer 400, the temperature of the base substrate 100 is decreased from the growth temperature of group III nitride crystal to room temperature. Thus, a laminated body including the base substrate 100, the base layer 200, the intermediate layer 300, and the cover layer 400 is formed.

At this time, the entire laminated body is warped due to a difference in linear expansion coefficient between the base substrate 100 and the group III nitride crystal layers including the base layer 200, the intermediate layer 300, and the cover layer 400, as shown in FIG. 3B. Specifically, since the linear expansion coefficient of sapphire as the base substrate 100 is greater than that of a group III nitride, the entire laminated body is warped such that the surface of the cover layer 400 becomes convex.

The base layer formation step S20, the intermediate layer formation step S30, and the cover layer formation step S40 described above are continuously performed in the same chamber without exposing the base substrate 100 to the atmosphere. This can suppress unintentional incorporation of at least any one of oxygen (O) and silicon (Si) as an n-type impurity at the interfaces between the base layer 200 and the intermediate layer 300 and between the intermediate layer 300 and the cover layer 400. As a result, the effect on the carrier concentration in these layers can be suppressed.

### (S50: Porous Step)

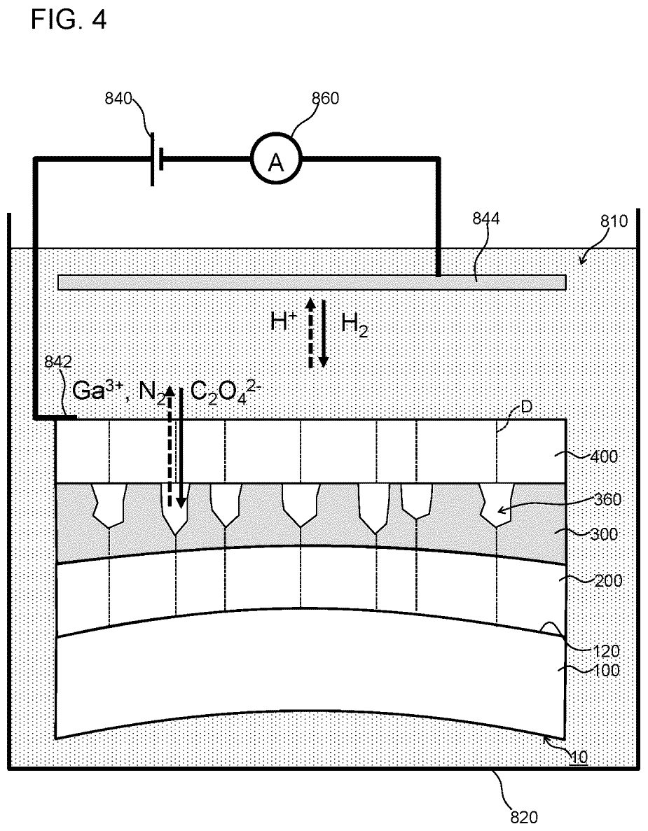

After forming the cover layer 400, as shown in FIG. 4, the intermediate layer 300 is made porous through the dislocations D in the cover layer 400 by performing the electrochemical process while maintaining the surface condition of the cover layer 400.

Specifically, the electrochemical process is performed, for example, by the following procedure.

As shown in FIG. 4, first, a process tank 820, a power source 840, and a current meter 860 are prepared. The power source 840 and the current meter 860 may be incorporated into one device as a current-voltage power source.

The process tank 820 is filled with an electrolyte 810. The electrolyte 810 is a solution containing ions capable of electrochemically etching a group III nitride. Examples of the electrolyte 810 include aqueous solutions containing oxalic acid, nitric acid, hydrofluoric acid, sulfuric acid, sodium sulfate (Na₂SO₄), sodium chloride (NaCl), sodium hydroxide (NaOH), and the like. Here, the electrolyte 810 is assumed to be an oxalic acid solution.

Furthermore, each electrode for performing the electrochemical process is prepared. Specifically, in a laminated body obtained after the completion of the above cover layer formation step S40, the anode 842 is provided on the surface of the cover layer 400, and the anode 842 is connected to the power source 840. Meanwhile, a cathode 844 is prepared. The cathode 844 is connected to the power source 840. For the cathode 844, a material that is resistant to corrosion but allows current to flow easily is used. Specific examples of the material for the cathode 844 include stainless steel (SUS), platinum (Pt), gold (Au), and boron-doped diamond.

After the connection of each electrode is completed, a stacked body with the anode 842 connected thereto and the cathode 844 are immersed into the electrolyte 810 in the process tank 820. In this state, a predetermined voltage is applied between the anode 842 and the cathode 844 by the power source 840. Thus, the electrochemical process is performed. At this time, the progress of the electrochemical process is checked based on a change in the current at the current meter 860.

At this time, by performing the electrochemical process, the electrolyte containing C₂O₄²⁻ is allowed to penetrate the dislocations D in the cover layer 400, which has a relatively low carrier concentration, toward the intermediate layer 300, which has a relatively high carrier concentration. That is, the dislocation D in the cover layer 400 is used as a nano-sized path through which the electrolyte penetrates. The electrolyte having reached the intermediate layer 300 in this way selectively etches the intermediate layer 300. This creates a plurality of voids 360 near the plurality of dislocations D in the intermediate layer 300. As a result, the intermediate layer 300 can be made porous.

On the other hand, according to the following reaction equation, group III element ions (Ga³⁺) and nitrogen (N₂) gas produced when etching the intermediate layer 300 are released through the dislocations D in the cover layer 400 to the outside of the cover layer 400.

2GaN+6h⁺→2Ga³⁺+N₂,
where “h⁺” is a positive charge.

Through the above electrochemical process, each of the plurality of voids 360 in the intermediate layer 300 is formed, for example, at a position overlapping each of the plurality of dislocations D in the cover layer 400 described later. The plurality of voids 360 in the intermediate layer 300 extends, for example, from a bottom surface of the cover layer 400 toward the base substrate 100 in the thickness direction. However, the voids 360 do not need to reach the base layer 200.

Meanwhile, partition wall portions of the intermediate layer 300 other than the voids 360 connect an upper portion of the base layer 200 or a lower portion of the intermediate layer 300 with the cover layer 400. Thus, the intermediate layer 300 maintains a constant thickness even though it has the plurality of voids 360.

At this time, in the present embodiment, the length of each of the plurality of voids 360 in the intermediate layer 300 in the direction along the main surface 120 of the base substrate 100 is, for example, 30 nm or more, or may be 100 nm or more, when viewed in any cross section orthogonal to the main surface 120 of the base substrate 100. Thus, in the regrowth step S60 described later, the voids 360 in the intermediate layer 300 can be maintained. As a result, in the peeling step S70 described later, the regrowth layer 500 can be easily and stably peeled off from the base substrate 100 by using, as the boundary, at least a portion of the intermediate layer 300 maintained in a porous state.

The upper limit of the length of each of the voids 360 in the intermediate layer 300 in the direction along the main surface 120 of the base substrate 100 is not limited. However, the length of each of the voids 360 in the direction along the main surface 120 of the base substrate 100 may be 10 μm or less. Thus, by adjusting conditions for the electrochemical process appropriately in the porous step S50, the cover layer 400 can be prevented from being peeled off due to outgassing that occurs when etching the intermediate layer 300.

At this time, in the present embodiment, the depth of each of the plurality of voids 360 in the thickness direction of the intermediate layer 300 is, for example, more than 100 nm, or 500 nm or more, or may be 1 μm or more. Also, with this configuration, in the regrowth step S60 described later, the voids 360 in the intermediate layer 300 can be maintained. As a result, in the peeling step S70 described later, the regrowth layer 500 can be easily and stably peeled off from the base substrate 100.

The upper limit of the depth of each of the voids 360 is not limited. However, the depth of the void 360 may be less than or equal to the thickness of the intermediate layer 300. Thus, in the peeling step S70 described later, excessive spread of the peeling from the intermediate layer 300 to other layers can be suppressed.

Meanwhile, in the electrochemical process, almost no etching occurs on the surface of the cover layer 400 having a relatively low carrier concentration. In other words, even when the cover layer 400 has the plurality of dislocations D as described above, excessive etching does not occur on the surface of the cover layer 400 near the dislocations D. Consequently, the surface condition of the cover layer 400 can be maintained flat.

At this time, in the present embodiment, after the porous step S50, the arithmetic mean roughness (Ra) of the surface of the cover layer 400 is, for example, 1.0 nm or less, and the root mean square roughness (RMS) of the surface of the cover layer 400 is, for example, 2.0 nm or less. Alternatively, the Ra of the surface of the cover layer 400 may be, for example, 0.5 nm or less, and the RMS of the surface of the cover layer 400 may be, for example, 1.0 nm or less. Here, Ra and RMS are the values obtained when the surface of the cover layer 400 is observed with an atomic force microscope (AFM) in a field of view of 5 μm square.

By maintaining a small surface roughness of the cover layer 400 as described above, a thick regrowth layer 500 with good crystallinity can be stably grown on the cover layer 400.

The lower limits of Ra and RMS of the surface of the cover layer 400 are not limited and may be close to the Ra and RMS of the main surface 120 of the base substrate 100, respectively. Specifically, the lower limits of Ra and RMS of the surface of the cover layer 400 may be 0.1 nm and 0.2 nm, respectively.

Specific conditions for the electrochemical process that can implement selective etching of the intermediate layer 300 described above are, for example, as follows. A processing voltage is adjusted based on the carrier concentration of the intermediate layer 300 or the like. A processing current is adjusted based on a process area (an area of the base substrate 100). A processing time is adjusted based on the thickness of the intermediate layer 300.
Electrolyte temperature: room temperature (10° C. or higher and 30° C. or lower)
Processing voltage: 1 V or more and 200 V or less, or 10 V or more and 20 V or less
Processing current: 0.01 mA or more and 60 A or less, or 0.1 mA or more and 10 A or less
Processing time: 0.1 min or more and 180 min or less, or 1 min or more and 30 min or less

As the intermediate layer 300 is made porous through the above electrochemical process, the cover layer 400 and the laminated body including the base substrate 100 and the base layer 200 are separated, while the intermediate layer 300 made porous is interposed therebetween, as shown in FIG. 4. The presence of the voids 360 with the above-mentioned size in the intermediate layer 300 can significantly facilitate this separation.

Thus, the warpage of the cover layer 400 in the porous step S50 can be reduced to be smaller than the warpage of the cover layer 400 before the porous step S50. That is, the cover layer 400 can be brought into a condition of being nearly flat.

Meanwhile, a seed substrate 10 is brought into a condition closer to a configuration where the group III nitride crystal layer on the base substrate 100 is thin. Thus, the warpage of the base substrate 100 in the porous step S50 can be reduced to be smaller than the warpage of the base substrate 100 before the porous step S50.

After the electrochemical process, the seed substrate 10 for nitride crystal growth is removed from the electrolyte in the process tank 820. Thereafter, the seed substrate 10 for nitride crystal growth that has been removed from the process tank 820 is washed with pure water or the like and dried. Consequently, the electrolyte remaining in the voids 360 of the intermediate layer 300 is removed. In the way above, the porous step S50 is completed.

In this way, the seed substrate 10 is obtained. The seed substrate 10 is used for the regrowth step S60 and the peeling step S70 described later.

### (S60: Regrowth Step)

After the porous step S50 is completed, the regrowth layer 500 comprising group III nitride crystal is epitaxially grown on the cover layer 400. The growing method for the regrowth layer 500 uses, for example, the vapor phase growth method.

In the present embodiment, crystal represented by the composition formula of AlₓGa₁₋ₓN, where an Al composition ratio x is 0.05 or more and 0.8 or less, is grown as the regrowth layer 500.

In the present embodiment, by growing the regrowth layer 500 comprising the AlGaN crystals described above on the flat cover layer 400 provided on the porous intermediate layer 300, the crystal strain generated in the regrowth layer 500 can be alleviated more than in a case where the porous step S50 is not performed.

Meanwhile, in the present embodiment, by setting the Al composition ratio x of the regrowth layer 500 to 0.05 or more and 0.8 or less, appropriate crystal strain can be applied to the porous intermediate layer 300. As a result, the peelability of the regrowth layer 500 using the intermediate layer 300 as the boundary can be improved.

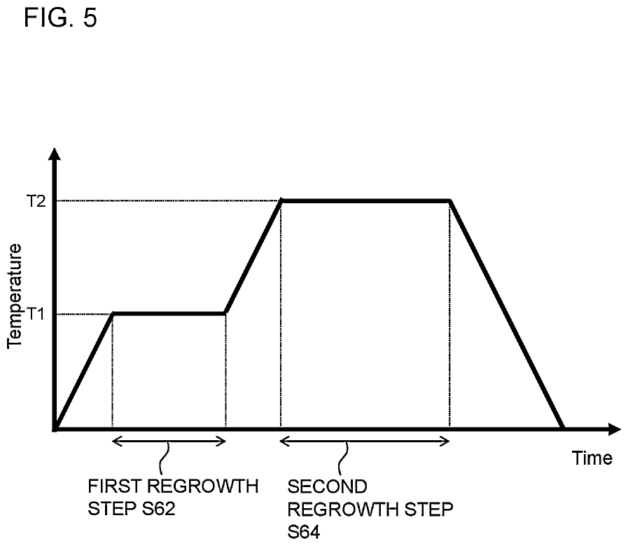

As shown in FIG. 5, in the regrowth step S60 of the present embodiment, the growth temperature may be adjusted in two stages. Specifically, the regrowth step S60 may have, for example, a first regrowth step S62 and a second regrowth step S64.

In this case, in the regrowth step S60, first, the temperature of the seed substrate 10 is increased from room temperature to a first growth temperature T1, as shown in FIG. 5.

### (S62: First Regrowth Step)

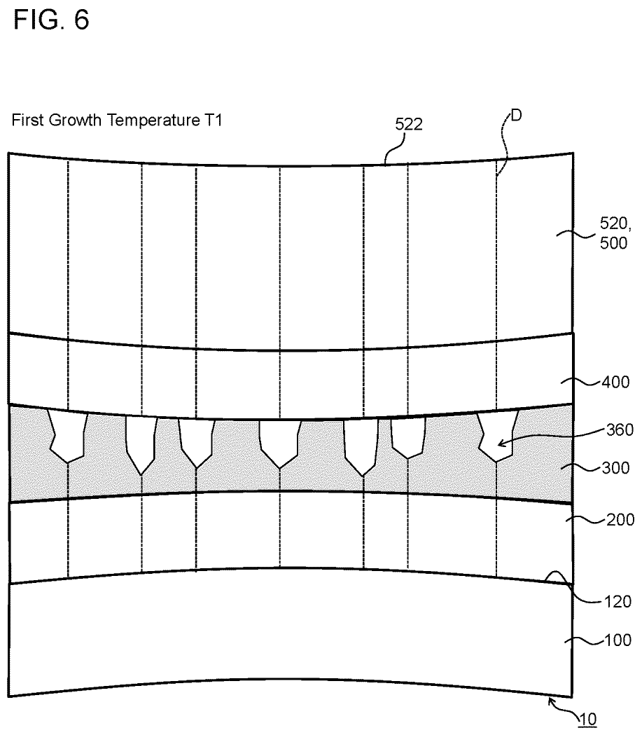

When the temperature of the seed substrate 10 reaches the first growth temperature T1, a first regrowth layer 520 is grown on the cover layer 400 at this first growth temperature T1, as shown in FIG. 6.

Specifically, an AlGaN layer is grown by supplying AlCl₃ gas, GaCl gas and NH₃ gas to the seed substrate 10 heated to the first growth temperature T1, for example, using the HVPE method. In the way above, the AlGaN layer is epitaxially grown on the surface of the cover layer 400 as the first regrowth layer 520. Various dopants may be added to the AlGaN layer as the first regrowth layer 520.

At this time, in the present embodiment, the first growth temperature T1 of the first regrowth step S62 is set lower than a second growth temperature T2 of the second regrowth step S64 as a main growth described later. That is, the first growth temperature T1 of the first regrowth step S62 is set slightly lower than the growth temperature of typical group III nitride crystal.

At this time, the base substrate 100 is elongated as the temperature increases from room temperature to the first growth temperature T1. However, since the first growth temperature T1 is lower (than the growth temperature of the base layer 200 and the like), the base substrate 100 does not become completely flat, with the main surface 120 of the base substrate 100 remaining slightly convex.

In contrast, since the linear expansion coefficient of the cover layer 400 is smaller than that of the base substrate 100, the elongation of the cover layer 400 is smaller than that of the base substrate 100. Consequently, the cover layer is warped such that the surface of the cover layer 400 is recessed. However, by making the first growth temperature T1 lower, excessive warpage of the cover layer 400 can be suppressed. Thus, the occurrence of cracks in the cover layer 400 can be suppressed. As a result, the occurrence of cracks in the regrowth layer 500 on the cover layer 400 can also be suppressed.

At this time, in the present embodiment, the first growth temperature T1 is set to 970° C. or lower, for example. This can stably suppress the occurrence of cracks in the cover layer 400 in the first regrowth step S62. As a result, the occurrence of cracks in the regrowth layer 500 on the cover layer 400 can be stably suppressed.

On the other hand, the first growth temperature T1 may be set to 800° C. or higher, for example. Thus, the group III nitride crystal can be stably grown as the first regrowth layer 520.

By adjusting the first growth temperature T1 as described above, the first regrowth layer 520 with a predetermined thickness can be grown on the cover layer 400 while suppressing the occurrence of cracks in the cover layer 400. Thus, the total thickness of the group III nitride crystal layers (cover layer 400 and first regrowth layer 520) above the intermediate layer 300 made porous can be stably thickened. As a result, in the second regrowth step S64 as the main growth described later, the group III nitride crystal layer above the intermediate layer 300 can be made less prone to cracking when the temperature is increased to the second growth temperature T2.

At this time, in the present embodiment, by starting the growth of the first regrowth layer 520 on the cover layer 400 with a flat surface, the regrowth layer 500 can be grown in a step-flow growth mode at least in an initial stage of the growth of the first regrowth layer 520 as the regrowth layer 500 (in a stage where the thickness thereof is thin). That is, in the initial stage of the growth, the island-shaped growth of the regrowth layer 500 comprising AlGaN crystal can be suppressed. Thus, the regrowth layer 500 as the continuous film comprising AlGaN crystal can be grown in the step-flow growth mode over the entire surface of the cover layer 400 with a c-plane 522 (+c-plane) as the growth surface. As a result, the Al composition ratio x can be made uniform in the plane of the first regrowth layer 520. Further, the crystallinity of the first regrowth layer 520 can be improved.

Thereafter, when the first regrowth layer 520 is gradually grown after the growth in the step-flow growth mode in the initial stage of the growth of the first regrowth layer 520, a tilted interface other than the c-plane may be generated in at least a portion of the first regrowth layer 520. That is, after the first regrowth layer 520 with the predetermined thickness is grown in the step-flow growth mode, the first regrowth layer 520 may be grown three-dimensionally. Thus, at least some of the plurality of dislocations D having propagated from the cover layer 400 in the direction along the c-axis of the first regrowth layer 520 can be bent and propagate toward the direction substantially perpendicular to the respective tilted interfaces at positions where the tilted interfaces are exposed. This allows at least some of the plurality of dislocations D to be locally collected. By eliminating the locally collected dislocations D, the dislocation density can be reduced. As a result, the number of pits on the surface of the regrowth layer 500 can also be reduced.

At this time, in the present embodiment, the thickness of the first regrowth layer 520 is, for example, 1 μm or more, or may be 10 μm or more, or 20 μm or more. Thus, in the second regrowth step S64 as the main growth described later, the group III nitride crystal layer above the intermediate layer 300 can be stably made less prone to cracking when the temperature is increased to the second growth temperature.

Meanwhile, the upper limit of the thickness of the first regrowth layer 520 is not particularly limited. However, the thickness of the first regrowth layer 520 is, for example, 300 μm or less, or may be 100 μm or less.

When the thickness of the first regrowth layer 520 reaches a predetermined thickness, the growth of the first regrowth layer 520 is terminated by stopping the supply of AlCl₃ gas and GaCl gas. However, the supply of NH₃ gas is still continued.

Thereafter, the temperature of the seed substrate 10 is increased from the first growth temperature T1 to the second growth temperature T2, as shown in FIG. 5.

### (S64: Second Regrowth Step)

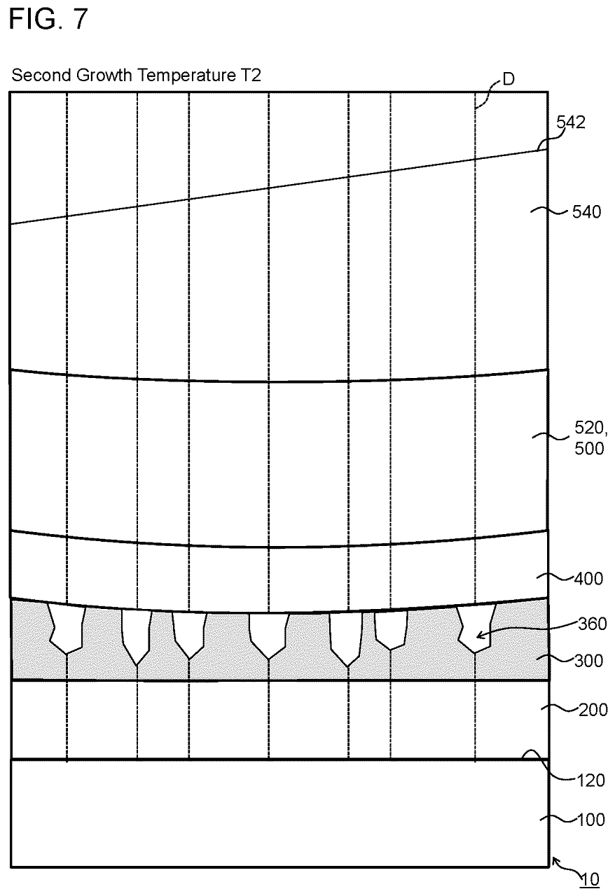

After increasing the temperature of the seed substrate 10 from the first growth temperature T1 to the second growth temperature T2, the growth of the regrowth layer 500 is resumed as the second regrowth layer 540, as shown in FIG. 7. That is, at the second growth temperature T2, the thick second regrowth layer 540 is grown as the main growth on the first regrowth layer 520.

Specifically, for example, the second regrowth step S64 is performed in the same chamber as the first regrowth step S62 without atmospheric exposure. In the second regrowth step S64, an AlGaN layer is epitaxially grown as the second regrowth layer 540 on the first regrowth layer 520 under the same conditions as in the first regrowth step S62, except that the growth temperature is set to the second growth temperature T2. Various dopants may be added in the AlGaN layer as the second regrowth layer 540.

At this time, in the present embodiment, even when the second growth temperature T2 of the second regrowth step S64 as the main growth is higher than the first growth temperature T1 of the first regrowth step S62, the group III nitride crystal layer above the intermediate layer 300 is made less prone to cracking because the total thickness of the cover layer 400 and first regrowth layer 520 as the group III nitride crystal layer above the intermediate layer 300 is set to be large, as described above. Thus, the regrowth layer 500 can be grown stably.

At this time, in the present embodiment, by setting the second growth temperature T2 of the second regrowth step S64 higher than the first growth temperature T1, the second regrowth layer 540 can be grown stably in the step-flow growth mode (grown two-dimensionally or grown in the lateral direction) with a c-plane 542 as the growth surface, as described above. Thus, the thick second regrowth layer 540 with good crystallinity can be grown while improving the surface flatness. Note that the c-axis, which is the normal of the c-plane 542 of the second regrowth layer 540, may be inclined at an off-angle that takes over the c-axis of the base substrate 100, which is inclined at a predetermined off-angle.

At this time, in the present embodiment, the second growth temperature T2 is, for example, 980° C. or higher, or may be 1000° C. or higher. Thus, the second regrowth layer 540 can be grown stably in the step-flow growth mode. As a result, the thick second regrowth layer 540 with good crystallinity can be grown stably while improving the flatness of the second regrowth layer 540.

Meanwhile, the second growth temperature T2 may be set to 1200° C. or lower, for example. This can suppress the roughening of the surface of the second regrowth layer 540 due to excessively high growth temperature.

At this time, in the case where the tilted interface is generated in at least a portion of the first regrowth layer 520 (the first regrowth layer 520 is grown three-dimensionally) in the first regrowth step S62 of the present embodiment, the second regrowth layer 540 is grown in the horizontal direction as described above, so that a tilted interface in the second regrowth layer 540 can be gradually shrunk, that is, the c-plane 542 can be gradually enlarged. Thus, the second regrowth layer 540 with the mirror-finished surface can be grown.

At this time, in the present embodiment, the total thickness of the regrowth layer 500 (the first regrowth layer 520 and the second regrowth layer 540) is, for example, 600 μm or more, and may be 1 mm or more. The upper limit of the thickness of the regrowth layer 500 is not particularly limited. However, from the viewpoint of improving productivity, the thickness of the regrowth layer 500 may be, for example, 100 mm or less.

Here, in the growth process of the thick regrowth layer 500, the dislocations D move in a random walk manner. Thus, the dislocations D are caused to gather or to form loops during the growth of the regrowth layer 500. Such a phenomenon can reduce the number of dislocations D reaching the surface of the thick second regrowth layer 540.

Alternatively, in the first regrowth step S62 of the present embodiment, in the case where the tilted interface is generated in at least a portion of the first regrowth layer 520 (the first regrowth layer 520 is grown three-dimensionally), the dislocations can be collected locally at portions where adjacent tilted interfaces gather during the process of growing the second regrowth layer 540 in the horizontal direction. Also in this case, the number of dislocations D reaching the surface of the thick second regrowth layer 540 can be reduced.

As a result, the dislocation density of the second regrowth layer 540 can be reduced. (Note that the number of dislocations in FIG. 7 is not reduced significantly for simplification of FIG. 7.)

### (S70: Peeling Step)

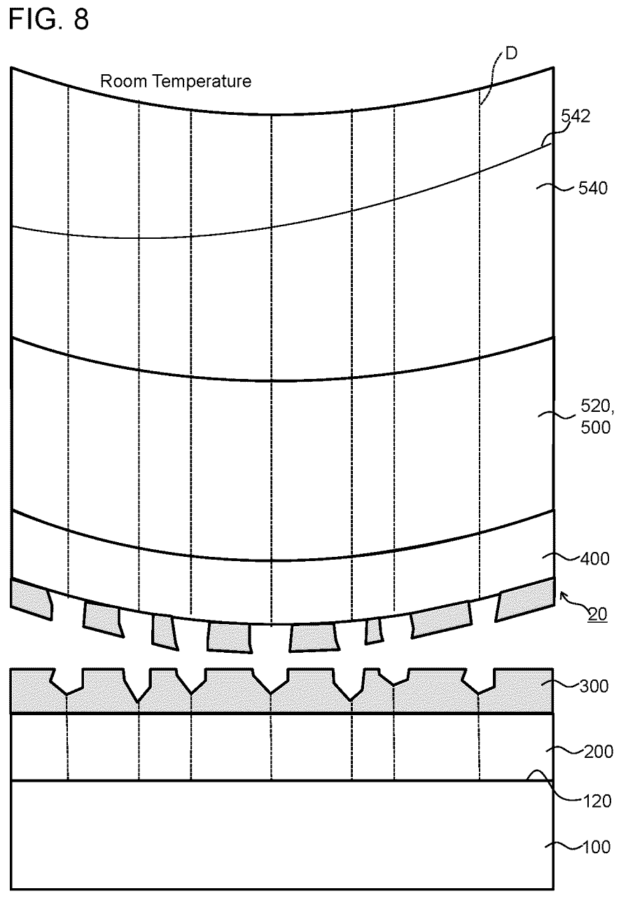

After the regrowth step S60 is completed, as shown in FIG. 8, the regrowth layer 500 is peeled off from the base substrate 100 by using at least a portion of the intermediate layer 300 made porous as the boundary.

In the present embodiment, the regrowth layer 500 is peeled off spontaneously from the base substrate 100 while decreasing the temperature after the regrowth step S60. This can eliminate the need for a special separate step of peeling. In other words, the manufacturing method can be simplified.

Here, in the regrowth step S60, tensile stress is generated in the regrowth layer 500 (in the direction along the main surface 120 of the base substrate 100). This is due to the fact that, for example, the dislocation density is reduced as the thickness of the regrowth layer 500 increases, as described above.

The tensile stress generated in the regrowth layer 500 in the direction along the main surface 120 of the base substrate 100 in this way warps the c-plane 510 of the regrowth layer 500 into a spherical shape with an upper side thereof recessed. Thus, the regrowth layer 500 is peeled off spontaneously and gradually from an outer periphery of the base substrate 100 toward a center thereof. That is, by utilizing the warpage of the c-plane 510 of the regrowth layer 500, the regrowth layer 500 can be gradually peeled off from the outer periphery toward the center of the base substrate 100. In other words, the regrowth layer 500 can be peeled off evenly in a concentric manner with respect to the center of the base substrate 100. As a result, the regrowth layer 500 with a large area can be peeled off easily and stably.

By the above peeling step S70, a peeled intermediate 20 including at least the cover layer 400 and the regrowth layer 500 is formed. Residual fragments of the intermediate layer 300 may remain on the bottom surface of the cover layer 400 of the peeled intermediate 20.

### (S80: Post-Process Step)

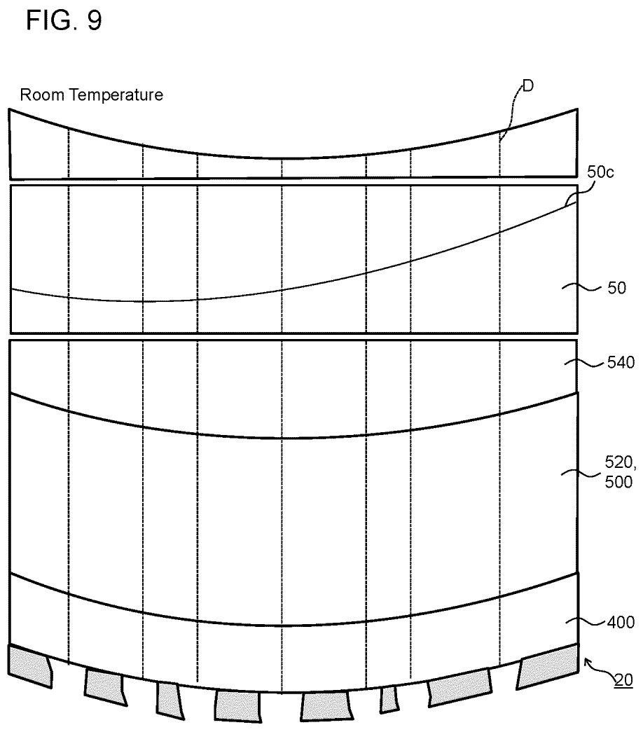

After the peeling step S70 is completed, the regrowth layer 500 is sliced by a wire saw, for example, along a cutting plane perpendicular to the normal direction at the center of the surface of the regrowth layer 500, as shown in FIG. 9. This forms a nitride crystal substrate 50 (which may be hereinafter abbreviated as the “substrate 50”) as an as-sliced substrate.

Next, both surfaces of the substrate 50 are polished by a polishing device. Thus, the main surface of the substrate 50 becomes mirror-finished.

Through the steps described above, the substrate 50 comprising the AlGaN crystal of the present embodiment is obtained.

### (Process for Fabricating Laminate or Semiconductor Device)

Thereafter, the substrate 50 described above may be used to fabricate a laminate or semiconductor device. The laminate or semiconductor device includes, for example, the substrate 50 described above and a semiconductor layer provided on the substrate 50 and including group III nitride crystal. This enables the production of a high-quality semiconductor device, such as an ultraviolet LED or an ultraviolet LD, for example.

### (2) Nitride Crystal Substrate

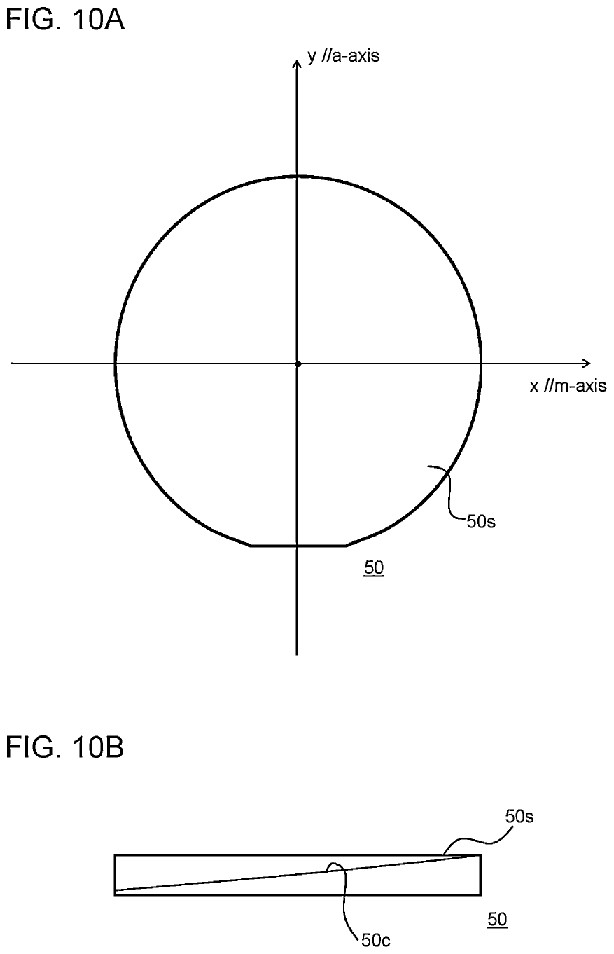

Referring to FIGS. 10A and 10B, the nitride crystal substrate 50 according to the present embodiment will be described.

In the present embodiment, the substrate 50 comprises crystal represented by the composition formula of AlₓGa₁₋ₓN, for example. The Al composition ratio x in the composition formula of the substrate 50 is, for example, 0.05 or more and 0.8 or less.

By setting the Al composition ratio x in the composition formula of the substrate 50 to 0.05 or more and 0.8 or less, the peelability of the regrowth layer 500 using the intermediate layer 300 as the boundary as described above can be improved, thus allowing the substrate 50 to be stably obtained from the regrowth layer 500.

From the viewpoint of application to semiconductor devices, by setting the Al composition ratio x in the composition formula of the substrate 50 to 0.05 or more, the UV light transmittance of the substrate 50 can be improved when the substrate 50 is applied to UV LEDs or UV LDs. On the other hand, if the Al composition ratio x in the composition formula of the substrate 50 is more than 0.8, Al vacancies occur more frequently. Consequently, the substrate 50 is prone to lose its conductivity. In contrast, by setting the Al composition ratio x in the composition formula of the substrate 50 to 0.8 or less, the frequency of the occurrence of Al vacancies can be suppressed. As a result, conductivity can be imparted to the substrate 50 comprising AlGaN crystal.

The diameter of the substrate 50 is, for example, 1 inch (25 mm) or more, or may be 2 inches (50 mm) or more, or 4 inches (100 mm) or more. Furthermore, the thickness of the substrate 50 is, for example, 300 μm or more and 1 mm or less.

The substrate 50 has a main surface 50s, for example, where the closest crystal plane with a low index is a c-plane 50c. The main surface 50s of the substrate 50 is, for example, mirror-finished. Thus, the main surface 50s of the substrate 50 has a root mean square roughness RMS of, for example, less than 1 nm.

In the present embodiment, the substrate 50 does not contain, for example, any polarity reversal zones (inversion domains) because the regrowth layer 500 is grown with the c-plane as a continuous growth surface.

In the present embodiment, the manufacturing method described above can alleviate the crystal strain generated in the regrowth layer 500 comprising AlGaN crystal. Consequently, the substrate 50 obtained from the regrowth layer 500 does not have any cracks.

In the present embodiment, the crystal strain generated in the regrowth layer 500 is alleviated, which also alleviates crystal strain in the substrate 50 obtained from the regrowth layer 500. Thus, the ratio a/c of a lattice constant in the a-axis direction to a lattice constant in the c-axis direction of the substrate 50 is close to the ratio a/c (=0.62) of strain-free AlGaN crystal.

Specifically, the substrate 50 satisfies the following formula (1):

$$0.58 \leq a / c \leq 0.66 \qquad ( 1 )$$

where c is a lattice constant in the <0001>-axis direction of the substrate 50, as determined based on a diffraction angle of a diffraction peak of (0002) of AlGaN by X-ray diffraction measurement (2θ-ω scan), and
a is a lattice constant in a <11-20>-axial direction of the substrate 50, as determined based on the c and a diffraction angle of a diffraction peak of (10-12) of AlGaN by the X-ray diffraction measurement (2θ-ω scan).

In the present embodiment, each of (0002) and (10-12) diffraction patterns of AlGaN of the substrate 50 obtained in the above X-ray diffraction measurements has a single peak.

In the present embodiment, the crystal strain generated in the regrowth layer 500 is alleviated, thus enabling the improvement in the crystallinity of the substrate 50 obtained from the regrowth layer 500.

Specifically, a Full Width at Half Maximum (FWHM) of the (0002) diffraction of AlGaN of the substrate 50 obtained by X-ray rocking curve measurement is, for example, 300 arcsec or less, or may be 100 arcsec or less.

The Full Width at Half Maximum (FWHM) of the (10-12) diffraction of AlGaN of the substrate 50 obtained by the X-ray rocking curve measurement is, for example, 500 arcsec or less, or may be 300 arcsec or less.

The X-ray rocking curve measurement is performed under the following conditions:
X-ray: monochromatic light of Kα1 of Cu obtained from an X-ray source via an X-ray mirror and two crystals on Ge(220)
Gonio radius: 420 mm
Incident slit width: 0.1 mm
Light-receiving slit side: Analyzer crystal

In the present embodiment, the regrowth layer 500 comprising AlGaN crystal is grown as the continuous film, instead of growing the regrowth layer 500 in the shape of islands, so that the Al composition ratio x remains uniform in the thickness direction of the regrowth layer 500. Thus, in the substrate 50 obtained from the regrowth layer 500, an Al composition ratio xr of a back surface of the substrate 50 and an Al composition ratio xm of the main surface of the substrate 50 are equal or close to each other.

Specifically, a ratio xm/xr of the Al composition ratio xm in a region from the main surface 50s of the substrate 50 to a position of 35 μm in the thickness direction to the Al composition ratio xr in a region from the back surface of the substrate 50 to a position of 35 μm in the thickness direction is, for example, 0.9 or more and 1.1 or less.

The Al composition ratios xr and xm as used herein are determined based on the diffraction angles of the (0002) diffraction peaks on the back and main surfaces of the substrate 50, respectively, by the X-ray diffraction measurement.

The position of “35 μm” in the thickness direction from each surface is a penetration length from each surface in the X-ray diffraction measurement when using the Cu Kα1 line.

In the substrate 50 obtained from the regrowth layer 500, an Al composition ratio xo at an outer periphery of the main surface of the substrate 50 and an Al composition ratio xc at the center of the main surface of the substrate 50 are equal or close to each other.

Specifically, a ratio xc/xo of the Al composition ratio xc at the center of the main surface 50s of the substrate 50 to the Al composition ratio xo at a position of 5 mm from the outer periphery toward the center of the main surface 50s of the substrate 50 is, for example, 0.9 or more and 1.1 or less.

The Al composition ratios xo and xc as used herein are determined based on the diffraction angles of the (0002) diffraction peaks on the outer peripheral side and center of the main surface of the substrate 50, respectively, by the X-ray diffraction measurement.

In the present embodiment, dislocations can be reduced during the growth process of the thick regrowth layer 500. This allows the dislocation density to be reduced in the substrate 50 comprising AlGaN crystal, obtained from the regrowth layer 500.

Specifically, the dislocation density at the main surface 50s of the substrate 50 is, for example, 3×10⁸ cm⁻² or less, or may be 1×10⁷ cm⁻² or less, 5×10⁶ cm⁻² or less, or 3×10⁶ cm⁻² or less.

The conductivity type of the substrate 50 is not particularly limited. However, the substrate 50 of the present embodiment may be of, for example, an n-type. In this case, examples of n-type impurities include Si, germanium (Ge), oxygen (O), and tin (Sn). The concentration of n-type impurities in the substrate 50 may be, for example, 1×10¹⁷ cm⁻³ or more and 1×10¹⁹ cm⁻³ or less.

Alternatively, the substrate 50 of the present embodiment may be of, for example, a p-type. In this case, the substrate 50 may contain, for example, magnesium (Mg). The Mg concentration in the substrate 50 may be, for example, 1×10¹⁶ cm⁻³ or more.

Alternatively, the substrate 50 of the present embodiment may be, for example, semi-insulating. In this case, the substrate 50 may contain, for example, iron (Fe), manganese (Mn) or carbon (C). The concentration of Fe, Mn or C in the substrate 50 may be, for example, 1×10¹⁶ cm⁻³ or more.

### (3) Summary of Present Embodiment

According to the present embodiment, one or more of the following effects can be obtained.
(a) In the present embodiment, the regrowth layer 500 comprising AlGaN crystal is grown on the cover layer 400 provided on the porous intermediate layer 300, thus making it possible to alleviate stress applied to the regrowth layer 500 through the porous intermediate layer 300, which is easily deformed.
(b) Furthermore, the regrowth layer 500 comprising AlGaN crystal is grown on the flat cover layer 400, thus allowing the regrowth layer 500 to be grown as the continuous film while suppressing island-shaped growth of the regrowth layer 500. This enables the Al composition ratio x to be made uniform over the entire regrowth layer 500.

By growing the regrowth layer 500 as described in (a) and (b), the crystal strain generated in the regrowth layer 500 comprising AlGaN can be alleviated. Consequently, the occurrence of cracks in the regrowth layer 500 can be suppressed. Furthermore, the crystallinity of the regrowth layer 500 can be improved. As a result, the substrate 50 comprising high-quality AlGaN crystal can be stably obtained from the regrowth layer 500.

By using the above-mentioned substrate 50 obtained in the present embodiment, high-quality semiconductor devices such as ultraviolet LEDs or ultraviolet LDs, for example, can be produced.
(c) In the present embodiment, while alleviating a crystal strain applied to the regrowth layer 500, an appropriate crystal strain can be applied to the porous intermediate layer 300.

By setting the Al composition ratio x of the regrowth layer 500 to 0.05 or more, appropriate crystal strain can be added to the porous intermediate layer 300 as the regrowth layer 500 grows, due to the lattice mismatch between the regrowth layer 500 and the layer located below the regrowth layer 500. This can enhance the fragility of the porous intermediate layer 300. As a result, the peelability of the regrowth layer 500 using the intermediate layer 300 as the boundary can be improved.

On the other hand, by setting the Al composition ratio x of the regrowth layer 500 to 0.8 or less, it is possible to prevent crystal strain from being excessively generated in the porous intermediate layer 300 due to the lattice mismatch between the regrowth layer 500 and the layer located below the regrowth layer 500. This can suppress the disappearance of the voids 360 in the intermediate layer 300 and can prevent the adhesion between the regrowth layer 500 and the layer located below the regrowth layer 500. As a result, the degradation in the peelability of the regrowth layer 500 using the intermediate layer 300 as the boundary can be suppressed.

As described above, the substrates 50 comprising AlGaN crystal can be obtained stably from the viewpoint of the peelability of the regrowth layer 500.

### (4) Modification Example of One Embodiment

The above embodiment can be modified as needed, as described in the following modification examples. Hereinafter, only components that differ from those in the above embodiment will be described. Components that are substantially the same as those in the above embodiment are denoted by the same reference characters, and descriptions thereof are omitted.

### Modification Example 1

In a cover layer formation step S40 of Modification Example 1, for example, crystal represented by the composition formula of AlₓGa₁₋ₓN may be grown as the cover layer 400. At this time, the Al composition ratio x in the cover layer 400 is, for example, more than 0 and 1 or less, or may be 0.05 or more and 0.8 or less.

According to Modification Example 1, AlGaN crystal is grown as the cover layer 400, thereby allowing the regrowth layer 500 to be grown homo-epitaxially on the cover layer 400. This can stably grow the regrowth layer 500 with good crystallinity.

### Modification Example 2

In a first regrowth step S62 of Modification Example 2, the growth temperature may be gradually increased from the first growth temperature T1 to the second growth temperature T2 while growing the first regrowth layer 520.

According to Modification Example 2, the rate of temperature increase from the first growth temperature T1 to the second growth temperature T2 can be slowed down. As a result, cracks in the group III nitride crystal layer above the intermediate layer 300 that would be caused by the temperature increase step from the first growth temperature T1 to the second growth temperature T2 can be stably suppressed.

### Modification Example 3

In a regrowth step S60 of Modification Example 3, the growth temperature of the regrowth layer 500 may be adjusted in one stage. That is, the temperature of the seed substrate 10 may be directly increased from room temperature to a growth temperature of the regrowth step S60 (which corresponds to the second growth temperature T2 described above).

According to Modification Example 3, the first regrowth step S62 can be omitted. As a result, the manufacturing process can be shortened.

### Other Embodiments of Present Disclosure

The embodiments of the present disclosure have been specifically described above. However, the present disclosure is not limited to the embodiments described above, and can be modified in various ways without departing from its gist.

In the embodiments described above, the base layer formation step S20 is performed, but the base layer formation step S20 may not be performed. That is, the base layer 200 may be eliminated. In the intermediate layer formation step S30, the intermediate layer 300 may be formed directly on the base substrate 100.

In the embodiments described above, an upper layer of the base layer 200 and the intermediate layer 300, each include GaN crystal, but the present disclosure is not limited to this case. Each layer is not limited to GaN crystal, but may comprise, for example, group III nitride crystal such as aluminum nitride (AlN), aluminum gallium nitride (AlGaN), indium nitride (InN), indium gallium nitride (InGaN), and aluminum indium gallium nitride (AlInGaN), that is, crystal represented by a composition formula of InₓAl_{y}Ga_{1-x-y}N (0≤x≤1, 0≤y≤1, 0≤x+y≤1).

In the embodiments described above, the base substrate 100 comprises a material different from a group III nitride, but the present disclosure is not limited to this case. The base substrate 100 may be a free-standing substrate comprising, for example, group III nitride crystal.

In the embodiments described above, the upper layer of the base layer 200, the intermediate layer 300, the cover layer 400, and the regrowth layer 500 each contain Si as the n-type impurity, but at least any one of the upper layer of the base layer 200, the intermediate layer 300, the cover layer 400, and the regrowth layer 500 may contain, for example, O or Ge as the n-type impurity.

In the embodiments described above, the above-mentioned respective vapor phase growth methods are used as growth methods for the base layer 200, the intermediate layer 300, the cover layer 400, and the regrowth layer 500, but the present disclosure is not limited to this case. A metal organic vapor phase epitaxy (MOVPE) method may be used as the growth method for at least any one of the base layer 200, the intermediate layer 300, the cover layer 400, and the regrowth layer 500. Alternatively, a growth method other than the vapor phase growth method may be used as the growth method for at least any one of the base layer 200, the intermediate layer 300, the cover layer 400, and the regrowth layer 500.

In the embodiments described above, the first regrowth layer 520 is grown three-dimensionally after the growth in the step-flow growth mode in the initial stage of the growth of the first regrowth layer 520, but the present disclosure is not limited to this case. The growth of the first regrowth layer 520 in the step-flow growth mode may be maintained.

### Examples

The following is a description of experimental results that support the effectiveness of the above-mentioned embodiments.

### (1) Fabrication of Samples

The following three samples were fabricated.

### [Sample A]

A nitride crystal substrate of Sample A was fabricated by the production method of the embodiment described above, according to the following procedure.

### (Base Substrate Preparation Step)

A base substrate for obtaining a seed substrate was prepared.
Base substrate: Sapphire substrate
Surface orientation of main surface of base substrate: +c-plane
Diameter of base substrate: 2 inches (50.8 mm)
Thickness of base substrate: 430 μm

### (Base Layer Formation Step)

An AlN buffer layer and a GaN layer were formed on the base substrate in this order as the base layer by the HVPE method under the following conditions.
Growth temperature of base layer: 1055° C.
Thickness of AlN buffer layer and GaN layer: 100 nm and 4 μm, respectively
Carrier concentration in GaN layer as base layer: about 1×10¹⁸ cm⁻³

### (Intermediate Layer Formation Step)

Next, a Si-doped GaN layer was grown as the intermediate layer on the base layer by the HVPE method under the following conditions.
Growth temperature of intermediate layer: 1055° C.
Thickness of intermediate layer: 3000 nm
Carrier concentration in intermediate layer: 6×10¹⁸ cm⁻³

### (Cover Layer Formation Step)

Next, a GaN layer was grown as the cover layer on the base layer by the HVPE method under the following conditions.
Growth temperature of cover layer: 1055° C.
Thickness of cover layer: 150 nm
Carrier concentration in cover layer: about 5×10¹⁷ cm⁻³

### (Porous Step)

Next, the intermediate layer was made porous through dislocations in the cover layer by performing the electrochemical process under the following conditions.
Electrolyte temperature: room temperature (23° C.)
Processing voltage: 20 V
Processing current: 100 mA as the maximum
Processing time: 10 min

### (First Regrowth Step)

Next, an Al_{0.6}Ga_{0.4}N layer was grown as the first regrowth layer on the cover layer by the HVPE method under the following conditions.
First growth temperature: 835° C.
Thickness of first regrowth layer: 50 μm

### (Second Regrowth Step)

Next, an Al_{0.6}Ga_{0.4}N layer was grown as the second regrowth layer on the first regrowth layer in the same chamber as in the first regrowth step.
Second growth temperature: 1055° C.
Total thickness of regrowth layers: 1 mm

### (Peeling Step)

The regrowth layer was peeled off from the base substrate as the temperature was decreased after the regrowth step.

### (Post-Process Step)

A nitride crystal substrate was formed by slicing the peeled regrowth layer. After the slicing, both surfaces of the nitride crystal substrate were polished to obtain a nitride crystal substrate with a thickness of 430 μm, comprising Al_{0.6}Ga_{0.4}N crystal, as Sample A1.

### [Sample B1 (Growth Directly on GaN Free-Standing Substrate)]

In the fabrication of Sample B1, a GaN free-standing substrate was used as the base substrate. An Al_{0.6}Ga_{0.4}N layer with a thickness of 1 mm was grown as the main growth layer directly on the GaN free-standing substrate by the HVPE method under the same conditions as those of the second regrowth layer in Sample A. This produced a laminate of Sample B1.

### [Sample B2 (VAS Method)]

In the fabrication of Sample B2, the VAS method was employed. First, a template was prepared on a sapphire substrate with a diameter of 2 inches, the template including a GaN layer of 300 nm in thickness with voids, and a mesh-shaped TiN layer of 20 nm in thickness in this order. Next, an Al_{0.6}Ga_{0.4}N layer with a thickness of 1 mm was grown as a main growth layer on the above GaN and TiN layers by the HVPE method under the same conditions as those of the second regrowth layer in Sample A. The main growth layer was then peeled off from the sapphire substrate, using the GaN layer with the voids as the boundary. This formed an Al_{0.6}Ga_{0.4}N layer of Sample B2.

### (2) Evaluation [Optical Microscope]

Each sample was observed with an optical microscope.

### [X-Ray Diffraction Measurement]

X-ray diffraction measurements (2θ-ω scans) of the (0002) and (10-12) of AlGaN were performed on the nitride crystal substrate of Sample A. Measurement positions included the center of a main surface of the nitride crystal substrate of Sample A, points set at intervals of 1 cm on a straight line extending along the m-axis direction and passing through the center of the main surface, and points set at intervals of 1 cm on another straight line along the a-axis direction orthogonal to the m-axis direction, which also passes through the center of the main surface. The a/c of the nitride crystal substrate of Sample A was determined based on the results obtained from the X-ray diffraction measurements.

The ratio xc/xo was determined by performing X-ray diffraction measurement on the nitride crystal substrate of Sample A, based on the Al composition ratio xc at the center of the main surface of the substrate to the Al composition ratio xo at a position of 5 mm from the outer periphery toward the center of the main surface of the substrate.

Furthermore, by performing the X-ray diffraction measurement in each of the above-mentioned measurement positions that overlap each other on the main and back surfaces of the nitride crystal substrate of Sample A, the ratio xm/xr was determined based on the Al composition ratio xm in a region from the main surface of the substrate to a position of 35 μm in the thickness direction thereof to the Al composition ratio xr in a region from the back surface of the substrate to a position of 35 μm in the thickness direction thereof.

### [X-Ray Rocking Curve Measurement]

The Full Width at Half Maximum (FWHM) of each of (0002) and (10-12) of AlGaN was determined by performing X-ray rocking curve measurement at each of the above-mentioned measurement positions on the nitride crystal substrate of Sample A.

### [Multiphoton Excitation Microscope]

The dislocation density was determined by observing the main surface at each of the above-mentioned measurement positions of the nitride crystal substrate of Sample A in a field of view of 250 μm square with a multiphoton excitation microscope.

### (3) Results

The results for Samples A, B1 and B2 will be described below.

### [Sample B1]

In Sample B1, cracks occurred in the main growth layer after the growth of the main growth layer on the GaN free-standing substrate. In Sample B1, it is considered that the cracks occurred in the main growth layer due to the lattice mismatch between the GaN free-standing substrate and the main growth layer comprising AlGaN crystal.

### [Sample B2]

In Sample B2, cracks occurred in a part of the main growth layer peeled off from the sapphire substrate. In Sample B2, the movement of Al atoms was reduced when island-shaped AlGaN crystal was grown three-dimensionally on the GaN layer with voids and the mesh-shaped TiN layer. This led to variations in Al composition ratio in the plane. Due to the variations in Al composition ratio, crystal strain was generated in the thick main growth layer comprising AlGaN crystal. As a result, it is considered that cracks occurred in the main growth layer in Sample B2.

### [Sample A]

In Sample A, no cracks occurred in either the peeled regrowth layer or the nitride crystal substrate obtained from the regrowth layer.

In Sample A, by growing the regrowth layer comprising AlGaN crystal on the flat cover layer provided on the porous intermediate layer, the crystal strain generated in the regrowth layer could be alleviated. As a result, it was confirmed that a nitride crystal substrate comprising high-quality AlGaN crystal without any cracks could be obtained in Sample A.

Furthermore, through additional analysis, it was confirmed that the nitride crystal substrate of Sample A demonstrated the following properties.

Ratio xc/xo of Al composition ratio: 1.07

It was confirmed that the following features were demonstrated at the respective measurement positions, including the center of the main surface of the nitride crystal substrate of Sample A and positions thereof set at intervals of 1 cm on a straight line extending along the m-axis direction and passing through the center of the main surface and on another straight line along the a-axis direction orthogonal to the m-axis direction, which also passes through the center of the main surface.

$$0.58 \leq a / c \leq 0.66 \qquad ( 1 )$$

FWHM of (0002) diffraction <250 arcsec
FWHM of (10-12) diffraction <450 arcsec
Dislocation density <3×10⁶ cm⁻²

Furthermore, it was confirmed that the following features were demonstrated at the respective measurement positions, including the respective centers of the main and back surfaces of the nitride crystal substrate of Sample A and positions thereof set at intervals of 1 cm on straight lines extending along the m-axis direction and passing through the respective centers of the main and back surfaces and on other straight lines along the a-axis direction orthogonal to the m-axis direction, which also pass through the respective centers of the main and back surfaces.
Ratio xm/xr of Al composition ratio: 0.95 to 1.05
Al composition ratio x: 0.59 to 0.63

### <Supplementary Descriptions>

Hereinafter, aspects of the present disclosure will be supplementarily described.

### (Supplementary Description 1)

A production method for a nitride crystal substrate, comprising:
(a) preparing a base substrate;
(b) forming an intermediate layer including n-type group III nitride crystal, above the base substrate;
(c) forming a cover layer on the intermediate layer, the cover layer including group III nitride crystal having a carrier concentration lower than a carrier concentration of the intermediate layer;
(d) making the intermediate layer porous through dislocations in the cover layer by performing an electrochemical process, while maintaining a surface condition of the cover layer;
(e) epitaxially growing a regrowth layer comprising group III nitride crystal, on the cover layer; and
(f) peeling off the regrowth layer from the base substrate by using at least a portion of the intermediate layer made porous as a boundary, wherein
in (e),
crystal represented by a composition formula of AlₓGa₁₋ₓN, where an Al composition ratio x is 0.05 or more and 0.8 or less, is grown as the regrowth layer.

### (Supplementary Description 2)

The production method for a nitride crystal substrate according to the supplementary description 1, wherein
in (e),
crystal strain generated in the regrowth layer is alleviated more than in a case where (d) is not performed.

### (Supplementary Description 3)

The production method for a nitride crystal substrate according to the supplementary description 1 or 2, wherein
in (e),
the regrowth layer is grown in a step-flow growth mode at least in an initial stage of the growth of the regrowth layer.

### (Supplementary Description 4)

The production method for a nitride crystal substrate according to any one of the supplementary descriptions 1 to 3, wherein
in (c),
GaN crystal is grown as the cover layer.

### (Supplementary Description 5)

The production method for a nitride crystal substrate according to any one of the supplementary descriptions 1 to 3, wherein
in (c),
crystal represented by a composition formula of AlₓGa₁₋ₓN, where an Al composition ratio x is more than 0 and 1 or less, is grown as the cover layer.

### (Supplementary Description 6)

The production method for a nitride crystal substrate according to any one of the supplementary descriptions 1 to 5,
(e) comprising:
(e1) growing a first regrowth layer on the cover layer at a first growth temperature; and
(e2) growing a second regrowth layer on the first regrowth layer at a second growth temperature, wherein
in (e1),
the first regrowth temperature is set lower than the second growth temperature.

### (Supplementary Description 7)

A nitride crystal substrate comprising crystal represented by a composition formula of AlₓGa₁₋ₓN, wherein
an Al composition ratio x of the composition formula is 0.05 or more and 0.8 or less, and
the nitride crystal substrate satisfies the following formula (1):

$$0.58 \leq a / c \leq 0.66 \qquad ( 1 )$$

where c is a lattice constant in a <0001>-axis direction of the nitride crystal substrate, as determined based on a diffraction angle of a diffraction peak of (0002) of AlGaN by X-ray diffraction measurement, and
a is a lattice constant in a <11-20>-axial direction of the nitride crystal substrate, as determined based on the c and a diffraction angle of a diffraction peak of (10-12) of AlGaN by the X-ray diffraction measurement.

### (Supplementary Description 8)

The nitride crystal substrate according to the supplementary description 7, wherein the nitride crystal substrate has a diameter of 25 mm or more and is free of cracks.

### (Supplementary Description 9)

The nitride crystal substrate according to the supplementary description 7 or 8, wherein
a full width at half maximum of (0002) diffraction of AlGaN of the nitride crystal substrate obtained by X-ray rocking curve measurement is 300 arcsec or less, and
a full width at half maximum of (10-12) diffraction of AlGaN of the nitride crystal substrate obtained by the X-ray rocking curve measurement is 500 arcsec or less.

### (Supplementary Description 10)

The nitride crystal substrate according to any one of the supplementary descriptions 7 to 9, wherein
the nitride crystal substrate has a main surface and a back surface opposite to the main surface, and
a ratio xm/xr of an Al composition ratio xm in a region from the main surface of the nitride crystal substrate to a position of 35 μm in a thickness direction to an Al composition ratio xr in a region from the back surface of the nitride crystal substrate to a position of 35 μm in the thickness direction is 0.9 or more and 1.1 or less.

### (Supplementary Description 11)

The nitride crystal substrate according to any one of the supplementary descriptions 7 to 10, wherein a ratio xc/xo of an Al composition ratio xc at a center of the main surface of the nitride crystal substrate to an Al composition ratio xo at a position of 5 mm from an outer periphery toward the center of the main surface of the nitride crystal substrate is 0.9 or more and 1.1 or less.

### (Supplementary Description 12)

A laminate comprising:
the nitride crystal substrate according to any one of the supplementary descriptions 7 to 11; and
a semiconductor layer provided on the nitride crystal substrate and including group III nitride crystal.

### REFERENCE SIGNS LIST

10 Seed substrate for nitride crystal growth
20 Peeled intermediate
50 Nitride crystal substrate
100 Base substrate
120 Main surface
200 Base layer
300 Intermediate layer
360 Void
400 Cover layer
500 Regrowth layer
520 First regrowth layer
540 Second regrowth layer
510 c-Plane
810 Electrolyte
820 Process tank
840 Power source
842 Anode
844 Cathode
860 Current meter

What is claimed is:

1. A production method for a nitride crystal substrate, comprising:
(a) preparing a base substrate;
(b) forming an intermediate layer including n-type group III nitride crystal, above the base substrate;
(c) forming a cover layer on the intermediate layer, the cover layer including group III nitride crystal having a carrier concentration lower than a carrier concentration of the intermediate layer;
(d) making the intermediate layer porous through dislocations in the cover layer by performing an electrochemical process, while maintaining a surface condition of the cover layer;
(e) epitaxially growing a regrowth layer comprising group III nitride crystal, on the cover layer; and
(f) peeling off the regrowth layer from the base substrate by using at least a portion of the intermediate layer made porous as a boundary, wherein
in (e),
crystal represented by a composition formula of AlₓGa₁₋ₓN, where an Al composition ratio x is 0.05 or more and 0.8 or less, is grown as the regrowth layer.

2. The production method for a nitride crystal substrate according to claim 1, wherein
in (e),
the regrowth layer is grown in a step-flow growth mode at least in an initial stage of the growth of the regrowth layer.

3. The production method for a nitride crystal substrate according to claim 1, wherein
in (c),
GaN crystal is grown as the cover layer.

4. The production method for a nitride crystal substrate according to claim 1, wherein
in (c),
crystal represented by a composition formula of AlₓGa₁₋ₓN, where an Al composition ratio x is more than 0 and 1 or less, is grown as the cover layer.

5. A nitride crystal substrate comprising crystal represented by a composition formula of AlₓGa₁₋ₓN, wherein
an Al composition ratio x of the composition formula is 0.05 or more and 0.8 or less, and
the nitride crystal substrate satisfies the following formula (1):
0.58≤a/c≤0.66 (1)
where c is a lattice constant in a <0001>-axis direction of the nitride crystal substrate, as determined based on a diffraction angle of a diffraction peak of (0002) of AlGaN by X-ray diffraction measurement, and
a is a lattice constant in a <11-20>-axial direction of the nitride crystal substrate, as determined based on the c and a diffraction angle of a diffraction peak of (10-12) of AlGaN by the X-ray diffraction measurement.

6. The nitride crystal substrate according to claim 5, wherein the nitride crystal substrate has a diameter of 25 mm or more and is free of cracks.

7. The nitride crystal substrate according to claim 5, wherein
a full width at half maximum of (0002) diffraction of AlGaN of the nitride crystal substrate obtained by X-ray rocking curve measurement is 300 arcsec or less, and
a full width at half maximum of (10-12) diffraction of AlGaN of the nitride crystal substrate obtained by the X-ray rocking curve measurement is 500 arcsec or less.
